(19) United States
(12) Patent Application Publication
(10) Pub. No.: US 2019/0319143 A1
(43) Pub. Date: Oct. 17, 2019

(54) SEMICONDUCTOR CRYSTAL SUBSTRATE, DEVICE, AND METHOD FOR MANUFACTURING SEMICONDUCTOR CRYSTAL SUBSTRATE

(71) Applicant: FUJITSU LIMITED, Kawasaki-shi (JP)

(72) Inventors: Shigekazu Okumura, Setagaya (JP); Shuichi Tomabechi, Atsugi (JP)

(73) Assignee: FUJITSU LIMITED, Kawasaki-shi (JP)

(21) Appl. No.: 16/454,662

(22) Filed: Jun. 27, 2019

Related U.S. Application Data
(63) Continuation of application No. PCT/JP2017/047068, filed on Dec. 27, 2017.

(30) Foreign Application Priority Data
Jan. 13, 2017 (JP) 2017-004360

(51) Int. Cl. H01L 31/0352; H01L 31/036; H01L 31/109; H01L 35/18; H01L 31/18; H01S 5/343; H01L 35/34; H01L 35/30; H01L 33/00; H01L 33/12; H01L 33/06; H01L 33/30; H01L 33/16; H01L 31/0304; H01S 5/34; H01S 5/02; H01L 31/105

(52) U.S. Cl. CPC H01L 31/035236; H01S 2304/02; H01L 31/109; H01L 35/18; H01L 31/184; H01S 5/343; H01L 35/34; H01L 35/30; H01L 33/0062; H01L 33/12; H01L 33/06; H01L 33/0025; H01L 33/30; H01L 33/16; H01L 31/0304; H01S 5/3422; H01S 5/0206; H01L 31/105; H01L 31/036

(57) ABSTRACT

A semiconductor crystal substrate includes: a crystal substrate whose principal surface is inclined relative to a (001) plane; and a superlattice structure layer including a first superlattice formation layer and a second superlattice formation layer, wherein the first superlattice formation layer is formed of Ga₁₋ₓ₁Inₓ₁As_{y1}Sb_{1-y1} (0≤x1≤0.1, 0≤y1≤0.1), and a value of a standard deviation to a mean value of atomic step widths in an inclination direction is equal to or greater than 0 and equal to or smaller than 0.20, and the second superlattice formation layer is formed of Ga₁₋ₓ₂Inₓ₂As_{y2}Sb_{1-y2} (0.9≤x2≤1, 0.9≤y2≤1), and a value of a standard deviation to a mean value of atomic step widths in an inclination direction is equal to or greater than 0 and equal to or smaller than 0.40.

### CROSS-REFERENCE TO RELATED APPLICATION

This application is a continuation application of International Application PCT/JP2017/047068 filed on Dec. 27, 2017 and designated the U.S., the entire contents of which are incorporated herein by reference. The International Application PCT/JP2017/047068 is based upon and claims the benefit of priority of the prior Japanese Patent Application No. 2017-004360, filed on Jan. 13, 2017, the entire contents of which are incorporated herein by reference.

### FIELD

The embodiments discussed herein relate to a semiconductor crystal substrate, an infrared detection device, an optical semiconductor device, a thermoelectric conversion element, a method for manufacturing a semiconductor crystal substrate, and a method for manufacturing an infrared detection device.

### BACKGROUND

An infrared detection device formed of a semiconductor material is used as a device for detecting infrared rays. One such infrared detection device is an infrared detection device having a structure in which an infrared absorbing layer is formed on a GaSb substrate with an InAs/GaSb superlattice structure. The InAs/GaSb superlattice structure to serve as an infrared absorbing layer is a type-II superlattice (T2SL) structure and has a type-II band line-up. Therefore, by adjusting the film thickness and the cycle of the superlattice in the InAs/GaSb superlattice structure, it is possible to obtain an infrared detection device having sensitivity for detection of wavelength bands from a middle wave (MW) having a wavelength of 3 to 5 μm to a long wave (LW) having a wavelength of 8 to 10 μm.

Japanese Laid-open Patent Publication No. 2012-9777 is an example of related art.

The following non-patent documents are examples of related art: O. Klin, et al., Journal of Crystal Growth 425 (2015) 54; and S. Okumura, et al., Abstract of IC-MBE2016, Tu-P-64.

### SUMMARY

According to an aspect of the embodiments, a semiconductor crystal substrate includes: a crystal substrate whose principal surface is inclined relative to a (001) plane; and a superlattice structure layer formed by alternately laminating a first superlattice formation layer and a second superlattice formation layer over the principal surface of the crystal substrate, wherein the first superlattice formation layer is formed of a layer of Ga₁₋ₓ₁Inₓ₁As_{y1}Sb_{1-y1} (0≤x1≤0.1, 0≤y1≤0.1), and a value of a standard deviation with respect to a mean value of atomic step widths in an inclination direction of a surface of the first superlattice formation layer (a value of the standard deviation/the mean value) is equal to or greater than 0 and equal to or smaller than 0.20, and the second superlattice formation layer is formed of a layer of Ga₁₋ₓ₂Inₓ₂As_{y2}Sb_{1-y2} (0.9≤x2≤1, 0.9≤y2≤1), and a value of a standard deviation with respect to a mean value of atomic step widths in an inclination direction of a surface of the second superlattice formation layer (a value of the standard deviation/the mean value) is equal to or greater than 0 and equal to or smaller than 0.40.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a structural diagram of a semiconductor crystal substrate in which a GaSb layer is formed on a GaSb substrate;

FIG. 2 is an AFM image of a surface of a GaSb layer formed on a GaSb substrate at a substrate temperature of 440° C.;

FIG. 3 is an AFM image of a surface of a GaSb layer formed on a GaSb substrate at a substrate temperature of 410° C.;

FIG. 4 is an AFM image of a surface of a GaSb layer formed on a GaSb substrate at a substrate temperature of 380° C.;

FIG. 5 is a structural diagram of a semiconductor crystal substrate in which an InAs layer is formed on a GaSb substrate;

FIG. 6 is an AFM image of a surface of an InAs layer formed on a GaSb substrate at a substrate temperature of 440° C.;

FIG. 7 is an AFM image of a surface of an InAs layer formed on a GaSb substrate at a substrate temperature of 410° C.;

FIG. 8 is an AFM image of a surface of an InAs layer formed on a GaSb substrate at a substrate temperature of 380° C.;

FIG. 9 is a structural diagram of a sample in which a superlattice structure layer is formed with a GaSb layer and an InAs layer;

FIGS. 10A to 10C are TEM images of the sample illustrated in FIG. 9;

FIG. 11 is an AFM image of a surface of an uppermost layer of the superlattice structure layer of the sample illustrated in FIG. 9;

FIG. 12 is a structural diagram of a semiconductor crystal substrate according to a first embodiment;

FIGS. 13A to 13C are process drawings (1) of a method for manufacturing the semiconductor crystal substrate according to the first embodiment;

FIGS. 14A and 14B are process drawings (2) of the method for manufacturing the semiconductor crystal substrate according to the first embodiment;

FIG. 15 is a structural diagram of an infrared detection device according to a second embodiment;

FIG. 16 is a structural diagram of a main section of the infrared detection device according to the second embodiment;

FIG. 17 is a perspective view of the infrared detection device according to the second embodiment;

FIGS. 18A and 18B are process drawings (1) of a method for manufacturing the infrared detection device according to the second embodiment;

FIGS. 19A and 19B are process drawings (2) of the method for manufacturing the infrared detection device according to the second embodiment;

FIGS. 20A and 20B are process drawings (3) of the method for manufacturing the infrared detection device according to the second embodiment;

FIGS. 21A and 21B are process drawings (4) of the method for manufacturing the infrared detection device according to the second embodiment;

FIG. 22 is a structural diagram of a semiconductor laser according to a third embodiment;

FIG. 23 is a structural diagram of a light emitting diode according to a fourth embodiment;

FIG. 24 is an explanatory diagram (1) of a thermoelectric conversion element according to a fifth embodiment; and

FIG. 25 is an explanatory diagram (2) of the thermoelectric conversion element according to the fifth embodiment.

### DESCRIPTION OF EMBODIMENTS

For example, a PIN type infrared detection device of the T2SL structure makes use of light absorption between bands. Therefore, it is expected that temperature characteristics are improved in comparison with a quantum dot infrared photodetector (QDIP) and a quantum well infrared photodetector (QWIP) that make use of light absorption between sub-bands. Such a PIN type infrared detection device having the T2SL structure may be required to have a high light receiving sensitivity and a low dark current in addition to the improvement in the above-described temperature characteristics.

In the PIN type infrared detection device of the T2SL structure, in order to achieve a high light receiving sensitivity and a low dark current, it may be required to form a high quality InAs/GaSb superlattice structure in the infrared absorbing layer, that is, to form an InAs/GaSb superlattice structure with fewer dislocations and lattice defects.

Accordingly, there is a request for a semiconductor crystal substrate having an InAs/GaSb superlattice structure with fewer dislocations and lattice defects.

Hereinafter, description of embodiments will be given. The same members or the like will be denoted by the same reference numerals, and description thereof will not be repeated. For the sake of convenience in explanation, the film thickness of each layer depicted in the drawings of the present application may not reflect the precise film thickness.

### First Embodiment

(GaSb)

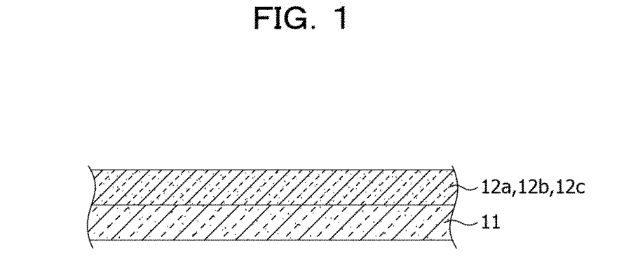

First, with regard to GaSb, a relationship between film formation conditions and flatness was examined. For example, as illustrated in FIG. 1, a GaSb layer 12a, a GaSb layer 12b, and a GaSb layer 12c different in film formation conditions were formed on a GaSb substrate 11, and flatness of each of surfaces of the GaSb layer 12a, GaSb layer 12b, and GaSb layer 12c was examined. The flatness of each of the surfaces of the GaSb layer 12a, GaSb layer 12b, and GaSb layer 12c was examined with an atomic force microscope (AFM). The GaSb layer 12a, GaSb layer 12b, and GaSb layer 12c were formed by MBE using a solid source, and V/III ratio was about 10.

As the GaSb substrate 11, a substrate whose principal surface was inclined by 0.35° relative to a (001) plane was used. Since the surface of the GaSb substrate 11 was oxidized to form an oxide film, the oxide film formed on the surface of the GaSb substrate 11 was removed by heating at about 500° C. in a vacuum.

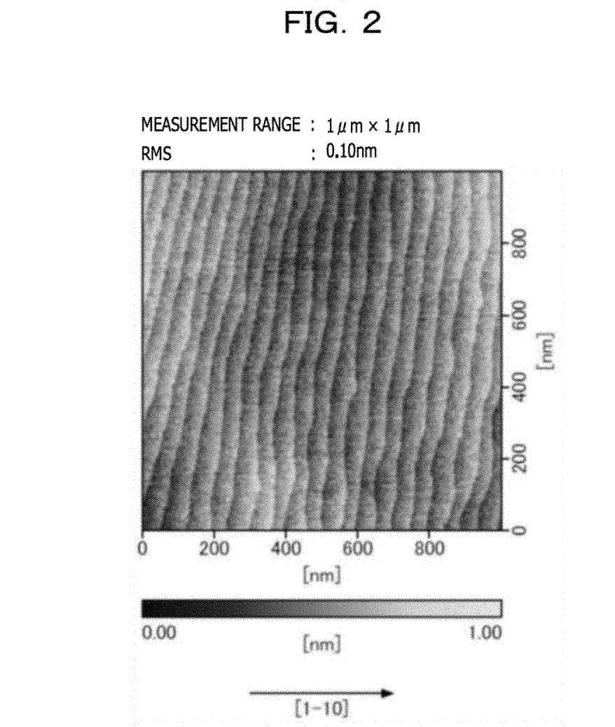

Next, the GaSb layer 12a having a film thickness of about 500 nm was formed by MBE on the GaSb substrate 11, from which the oxide film formed on the surface had been removed, under a condition of a substrate temperature of 440° C. An AFM image of the surface of the GaSb layer 12a formed in the above manner is given in FIG. 2. As seen in FIG. 2, on the surface of the GaSb layer 12a formed under the above-mentioned condition, a step reflecting the inclination of the principal surface of the GaSb substrate 11 appears. The surface roughness (RMS) of the GaSb layer 12a was 0.10 nm, the mean value of step widths in a [1-10] direction was 52.5 nm, the standard deviation of the step widths was 7.7 nm, and a value of the standard deviation/the mean value was 0.14.

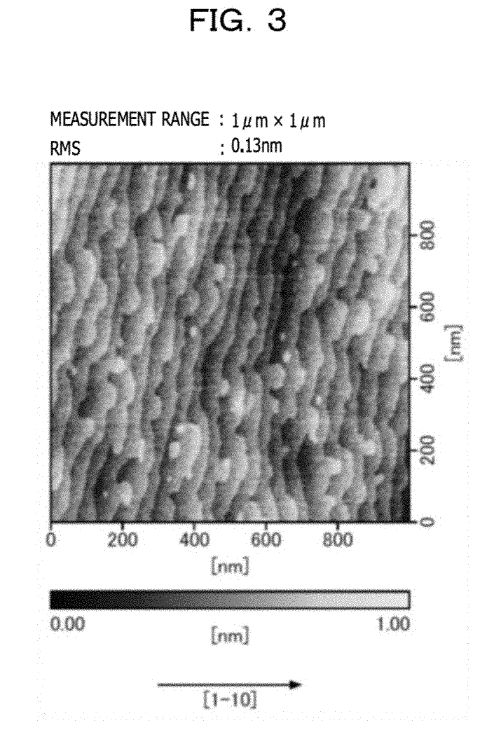

Next, the GaSb layer 12b having a film thickness of about 500 nm was formed by MBE on the GaSb substrate 11, from which the oxide film formed on the surface had been removed, under a condition of a substrate temperature of 410° C. An AFM image of the surface of the GaSb layer 12b formed in the above manner is given in FIG. 3. As seen in FIG. 3, on the surface of the GaSb layer 12b formed under the above-mentioned condition, a step reflecting the inclination of the principal surface of the GaSb substrate 11 appears. The surface roughness (RMS) of the GaSb layer 12b was 0.13 nm, the mean value of step widths in a [1-10] direction was 47.45 nm, the standard deviation of the step widths was 18.70 nm, and a value of the standard deviation/the mean value was 0.39.

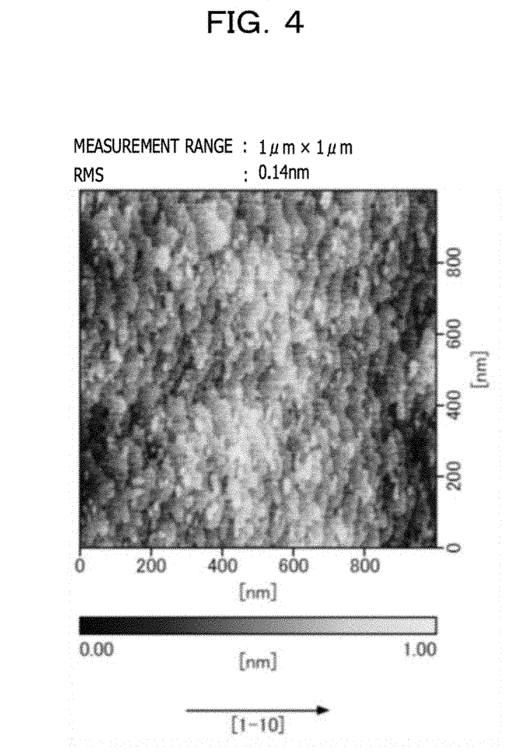

Next, the GaSb layer 12c having a film thickness of about 500 nm was formed by MBE on the GaSb substrate 11, from which the oxide film formed on the surface had been removed, under a condition of a substrate temperature of 380° C. An AFM image of the surface of the GaSb layer 12c formed in the above manner is given in FIG. 4. As seen in FIG. 4, on the surface of the GaSb layer 12c formed under the above-mentioned condition, a step reflecting the inclination of the principal surface of the GaSb substrate 11 was not observed, and the surface roughness (RMS) of the GaSb layer 12c was 0.14 nm.

As described above, when the GaSb layer is formed at a substrate temperature of 440° C., a film having a flat surface is obtained, but when it is formed at a substrate temperature of 410° C., the flatness of the surface is deteriorated. As the value of the standard deviation/the mean value on the surface is smaller, the flatness tends to be better. Therefore, in order to obtain a GaSb layer having good flatness, it is preferable to cause the value of the standard deviation/the mean value on the surface of the GaSb layer to be equal to or larger than 0 and equal to or smaller than 0.20.

(InAs)

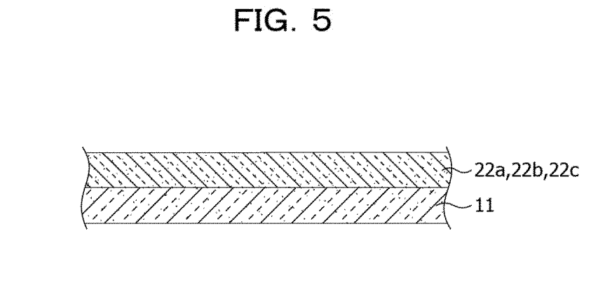

Next, with regard to InAs, a relationship between film formation conditions and flatness was examined. Specifically, as illustrated in FIG. 5, an InAs layer 22a, an InAs layer 22b, and an InAs layer 22c having different film formation conditions were each formed on the GaSb substrate 11, and the flatness of each of surfaces of the InAs layer 22a, InAs layer 22b, and InAs layer 22c was examined. The surface flatness of each of the InAs layer 22a, InAs layer 22b, and InAs layer 22c was examined with an AFM. The InAs layer 22a, InAs layer 22b, and InAs layer 22c were formed by MBE using a solid source, a growth rate was 0.2 μm/h, and V/III ratio was about 5.

As the GaSb substrate 11, a substrate whose principal surface was inclined by 0.35° relative to a (001) plane was used. Since the surface of the GaSb substrate 11 was oxidized to form an oxide film, the oxide film formed on the surface of the GaSb substrate 11 was removed by heating at about 500° C. in a vacuum.

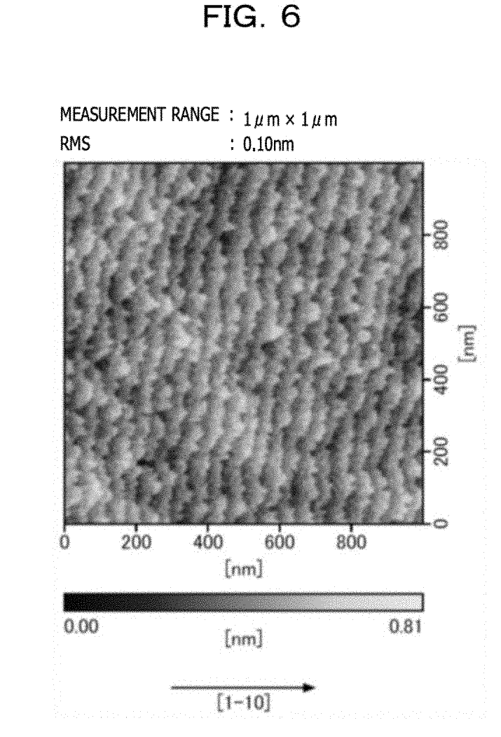

Next, the InAs layer 22a having a film thickness of about 100 nm was formed by MBE on the GaSb substrate 11, from which the oxide film formed on the surface had been removed, under a condition of a substrate temperature of 440° C. An AFM image of the surface of the InAs layer 22a formed in the above manner is given in FIG. 6. As seen in FIG. 6, on the surface of the InAs layer 22a formed under the above-mentioned condition, a step reflecting the inclination of the principal surface of the GaSb substrate 11 appears. The surface roughness (RMS) of the InAs layer 22a was 0.10 nm, the mean value of step widths in a [1-10] direction was 51.6 nm, the standard deviation of the step widths was 15.1 nm, and a value of the standard deviation/the mean value was 0.29.

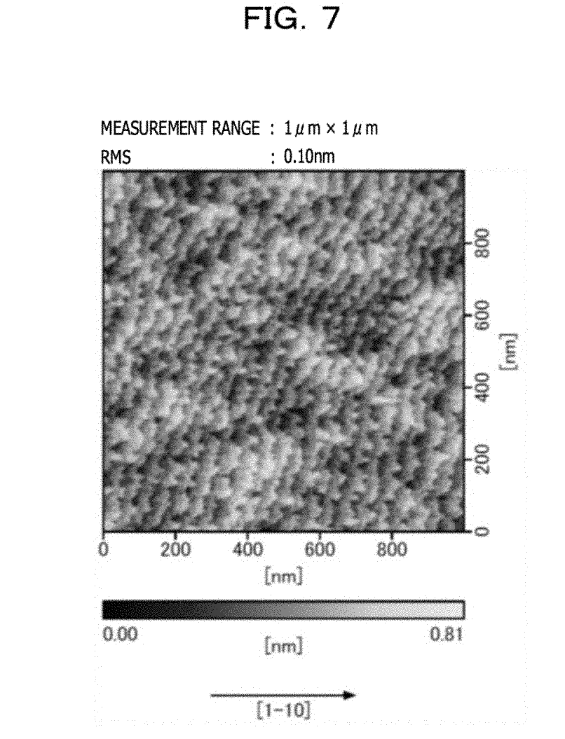

Next, the InAs layer 22b having a film thickness of about 100 nm was formed by MBE on the GaSb substrate 11, from which the oxide film formed on the surface had been removed, under a condition of a substrate temperature of 410° C. An AFM image of the surface of the InAs layer 22b formed in the above manner is given in FIG. 7. As seen in FIG. 7, on the surface of the InAs layer 22b formed under the above-mentioned condition, a step reflecting the inclination of the principal surface of the GaSb substrate 11 appears. The surface roughness (RMS) of the InAs layer 22b was 0.10 nm, the mean value of step widths in a [1-10] direction was 49.49 nm, the standard deviation of the step widths was 13.61 nm, and a value of the standard deviation/the mean value was 0.27.

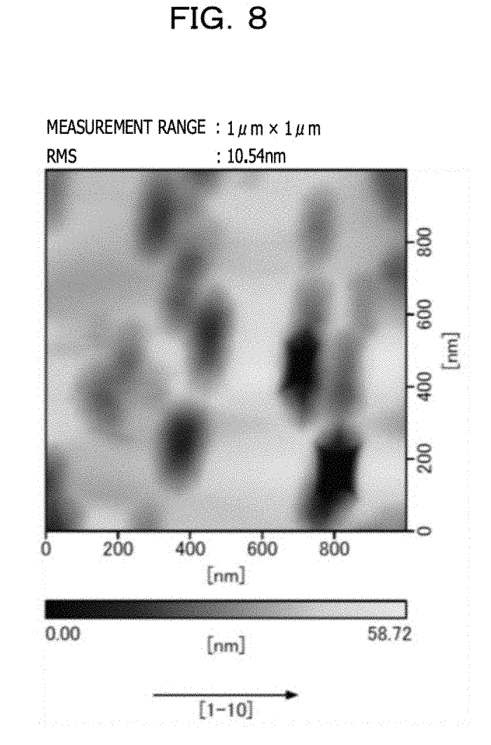

Next, the InAs layer 22c having a film thickness of about 100 nm was formed by MBE on the GaSb substrate 11, from which the oxide film formed on the surface had been removed, under a condition of a substrate temperature of 380° C. An AFM image of the surface of the InAs layer 22c formed in the above manner is given in FIG. 8. As seen in FIG. 8, on the surface of the InAs layer 22c formed under the above-mentioned condition, a step reflecting the inclination of the principal surface of the GaSb substrate 11 was not observed, and the surface roughness (RMS) of the InAs layer 22c was 10.54 nm.

As described above, when the InAs layer is formed at a substrate temperature of 440° C. or 410° C., a film having a flat surface is obtained, but when it is formed at a substrate temperature of 380° C., the flatness of the surface is deteriorated. As the value of the standard deviation/the mean value on the surface is smaller, the flatness tends to be better. Therefore, in order to obtain an InAs layer having good flatness, it is preferable to cause the value of the standard deviation/the mean value on the surface of the InAs layer to be equal to or larger than 0 and equal to or smaller than 0.40.

Some of the infrared detection devices and optical semiconductor devices using compound semiconductors have a superlattice structure in which films of different compositions or the like are alternately laminated and formed. In such a superlattice structure, in a case where the flatness of each of the films constituting the superlattice structure is not good, the desired characteristics may not be obtained; therefore, each of the films is required to be as flat as possible.

(Superlattice Structure)

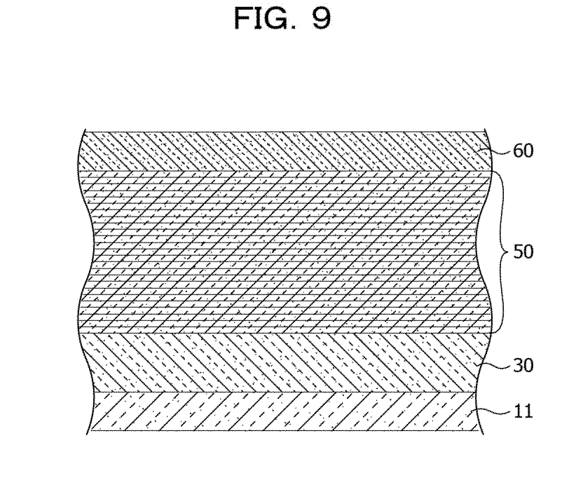

Next, as illustrated in FIG. 9, a sample to be used as a semiconductor crystal substrate having a superlattice structure was manufactured, where the sample was formed by alternately laminating the flat GaSb layers and the flat InAs layers obtained through the above-described experimental results. To be specific, manufactured was a semiconductor crystal substrate in which a GaSb buffer layer 30, a superlattice structure layer 50, and an i-InAs cap layer 60 were formed in sequence on the GaSb substrate 11.

The GaSb substrate 11 was formed with n-GaSb, and the principal surface thereof was inclined by 0.35° relative to the (001) plane. The GaSb buffer layer 30 was formed with i-GaSb not doped with impurity elements.

The superlattice structure layer 50 was formed by alternately laminating 20 pairs of the GaSb layer 12a formed at the substrate temperature of 440° C. and the InAs layer 22a formed at the substrate temperature of 440° C. The film thickness of the GaSb layer 12a forming the superlattice structure layer 50 was 2.8 nm to 3.6 nm, and the film thickness of the InAs layer 22a was 1.4 nm to 2.1 nm.

The i-InAs cap layer 60 was formed with InAs not doped with impurity elements.

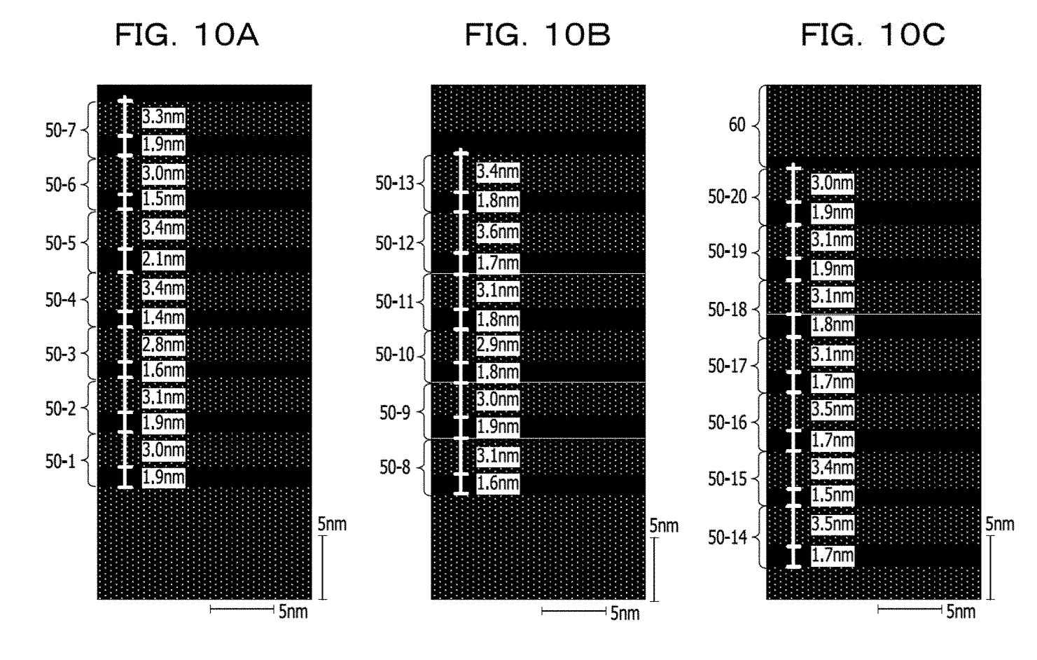

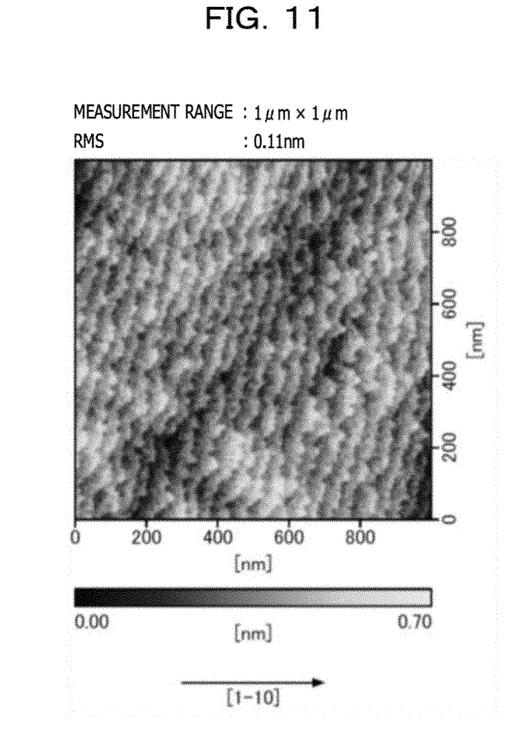

FIGS. 10A to 10C give cross-sectional transmission electron microscope (TEM) images of the superlattice structure layer 50 of the semiconductor crystal substrate formed in the above manner. In FIGS. 10A to 10C, reference numerals 50-1 to 50-20 respectively denote 20 pairs of the GaSb layer and the InAs layer formed in the superlattice structure layer 50. As seen in FIGS. 10A to 10C, in the superlattice structure layer 50 formed by alternately laminating the GaSb layers and the InAs layers, dislocations and lattice defects were not found so that a good superlattice structure was obtained. FIG. 11 is an AFM image of a surface of the uppermost layer of the superlattice structure layer 50, that is, an AFM image of a surface of the InAs layer indicated by the reference numeral 50-20 in FIG. 10C. As seen in FIG. 11, the surface roughness (RMS) is 0.11 nm, and the flatness is also good.

Accordingly, by alternately laminating the GaSb layers having good flatness and the InAs layers also having good flatness to form the superlattice structure layer 50, it is possible to obtain a good superlattice structure without dislocations or lattice defects.

(Semiconductor Crystal Substrate)

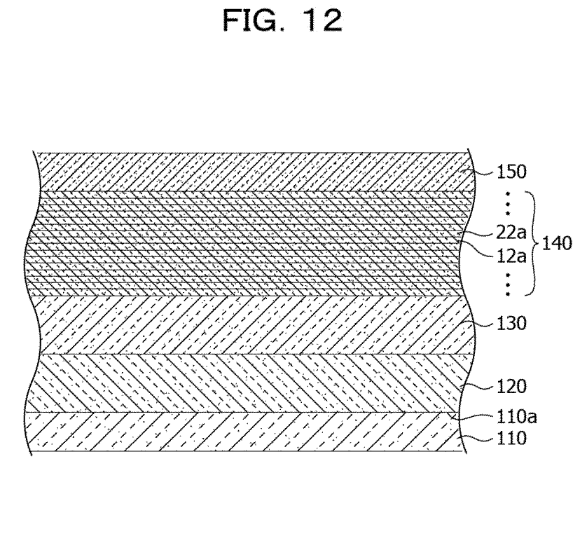

Next, a semiconductor crystal substrate according to the first embodiment will be described. As illustrated in FIG. 12, the semiconductor crystal substrate in the present embodiment is formed by sequentially laminating a GaSb buffer layer 120, a p-GaSb layer 130, a superlattice structure layer 140, and an n-InAs layer 150 on a GaSb substrate 110, which is a crystal substrate. Note that the semiconductor crystal substrate in the present embodiment may be a semiconductor crystal substrate in which the n-InAs layer 150 is not formed, or a semiconductor crystal substrate in which the p-GaSb layer 130 is not formed. For example, the semiconductor crystal substrate in the present embodiment may be formed by sequentially laminating the GaSb buffer layer 120, the p-GaSb layer 130, and the superlattice structure layer 140 on the GaSb substrate 110. Alternatively, the GaSb buffer layer 120, the superlattice structure layer 140, and the n-InAs layer 150 may be laminated and formed in sequence on the GaSb substrate 110.

The GaSb substrate 110 is formed with n-GaSb, and a principal surface 110a is inclined by 0.35° relative to the (001) plane. In this embodiment, the GaSb substrate 110 uses a substrate whose principal surface is inclined at an inclination angle of equal to or larger than 0.1° and equal to or smaller than 10° relative to the (001) plane. In a case of a GaSb substrate whose principal surface is not inclined, since the film growth mode is a two-dimensional nucleus growth (two-dimensional island growth) mode, it is difficult to obtain a film having good surface flatness. In contrast, by using a GaSb substrate whose principal surface is inclined, since the film growth mode comes to be a step flow growth mode, it is possible to obtain a film having good flatness. In this case, with a GaSb substrate having an inclination angle of smaller than 0.1° , since the substrate is almost similar to a substrate whose principal surface is not inclined, the film growth mode is likely to be a two-dimensional nucleus growth mode, rather than a step flow growth mode. If the inclination angle exceeds 10°, it is difficult to accurately measure the step width. In the present embodiment, a substrate made of GaAs, InP, InAs, or Si may be used instead of the GaSb substrate 110.

The GaSb buffer layer 120 is formed of an i-GaSb film having a film thickness of 100 mm and not doped with impurity elements.

The p-GaSb layer 130 is formed of a GaSb film having a film thickness of 500 nm and doped with Be as an impurity element to become a p-type.

The superlattice structure layer 140 is formed by alternately laminating 200 pairs of the GaSb layer 12a formed at the substrate temperature of 440° C. and the InAs layer 22a formed at the substrate temperature of 440° C. The film thickness of the GaSb layer 12a forming the superlattice structure layer 140 is about 2 nm, the film thickness of the InAs layer 22a is about 2 nm, and the total film thickness is about 800 nm. In the present application, the two layers forming the superlattice structure layer 140 may be referred to as a first superlattice formation layer and a second superlattice formation layer.

The GaSb layer 12a forming the superlattice structure layer 140 may be Ga₁₋ₓ₁Inₓ₁As_{y1}Sb_{1-y1} (0≤x1≤0.1, 0≤y1≤0.1). This is because the same tendency as GaSb may be obtained within the above range. The InAs layer 22a may be Ga₁₋ₓ₂Inₓ₂As_{y2}Sb_{1-y2} (0.9≤x2≤1, 0.9≤y2≤1). This is because the same tendency as InAs may be obtained within the above range.

In this embodiment, the superlattice structure layer 140 is formed so that a value of the standard deviation/the mean value on the surface of the GaSb layer 12a in the superlattice structure layer 140 is made to be equal to or greater than 0 and equal to or smaller than 0.20. Further, the superlattice structure layer 140 is formed so that a value of the standard deviation/the mean value on the surface of the InAs layer in the superlattice structure layer 140 is made to be equal to or greater than 0 and equal to or smaller than 0.40.

The n-InAs layer 150 is formed of an InAs film having a thickness of 100 nm and doped with Si as an impurity element to become an n-type.

(Method for Manufacturing Semiconductor Crystal Substrate)

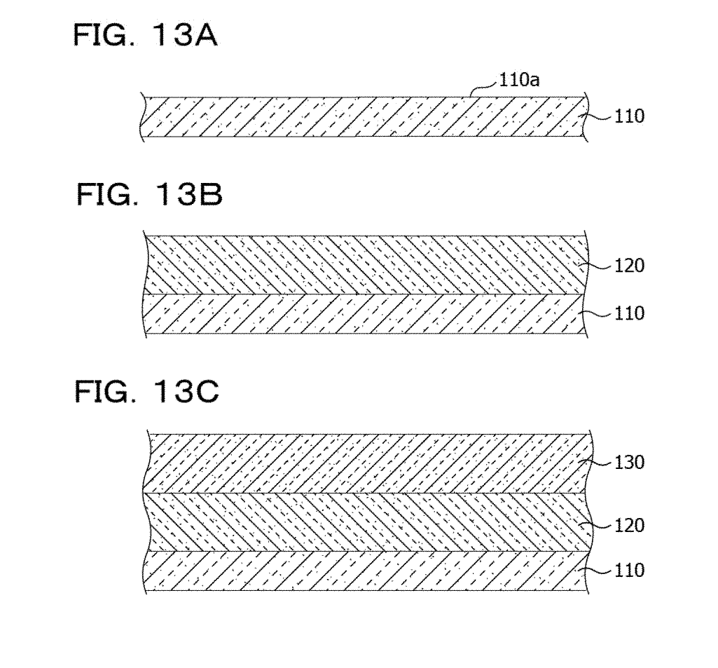

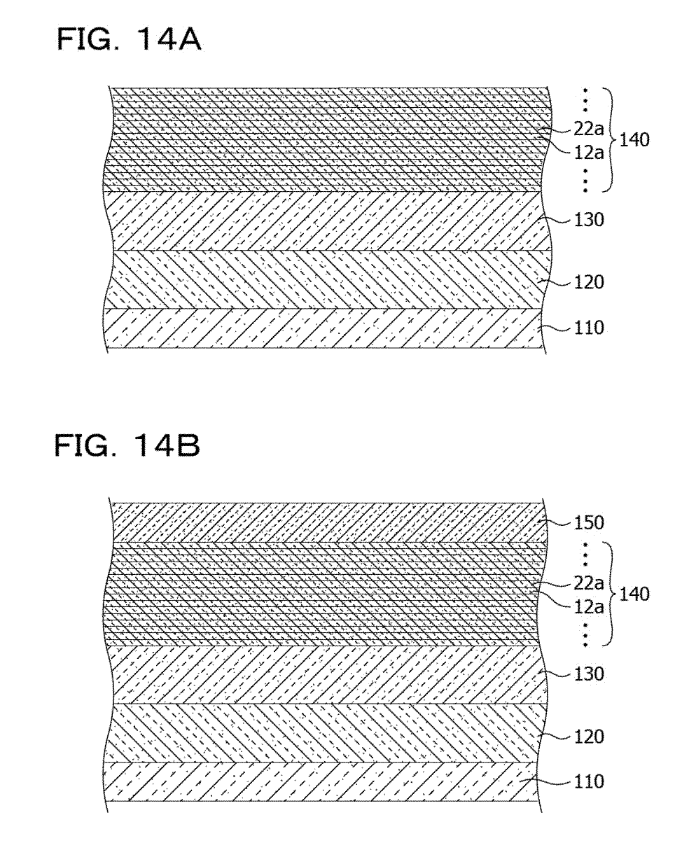

Next, a method for manufacturing a semiconductor crystal substrate according to the present embodiment will be described with reference to FIGS. 13A to 13C, and FIGS. 14A and 14B. First, as illustrated in FIG. 13A, the GaSb substrate 110 is placed in a vacuum chamber of a solid source molecular beam epitaxy (SS-MBE) apparatus. The GaSb substrate 110 is a GaSb substrate whose principal surface 110a is inclined by 0.35° relative to the (001) plane. Then, the GaSb substrate 110 is heated by a heater, and when the substrate temperature of the GaSb substrate 110 reaches 400° C., an Sb beam is radiated onto the surface of the GaSb substrate 110. The beam flux of Sb at this time is, for example, 5.0×10⁻⁷ Torr. Thereafter, when the GaSb substrate 110 is further heated, an oxide film of GaSb formed on the surface of the GaSb substrate 110 is desorbed at about 500° C. of a substrate temperature. Thereafter, the GaSb substrate 110 is heated to a substrate temperature of 530° C. in a state of being irradiated with the Sb beam, and the above state is maintained for 20 minutes, whereby the oxide film of GaSb formed on the surface of the GaSb substrate 110 is completely desorbed.

Next, as illustrated in FIG. 13B, the substrate temperature of the GaSb substrate 110 is lowered to 520° C. in a state of being irradiated with the Sb beam, and thereafter, the GaSb buffer layer 120 is formed on the GaSb substrate 110. For example, in a state where the substrate temperature of the GaSb substrate 110 is 520° C. and the Sb beam is being radiated, a Ga beam is further radiated to form the GaSb buffer layer 120. The beam flux of Ga at this time is, for example, 5.0×10⁻⁸ Torr, and V/III ratio is 10. The growth rate of the GaSb buffer layer 120 under the above conditions is 0.30 μm/h, and the film formation is performed for about 20 minutes until the film thickness of the GaSb buffer layer 120 comes to be 100 μm.

Subsequently, as illustrated in FIG. 13C, the p-GaSb layer 130 is formed on the GaSb buffer layer 120. For example, after the formation of the GaSb buffer layer 120, a Be beam is radiated while the Sb beam and the Ga beam being radiated, whereby the p-GaSb layer 130 is formed. At this time, the temperature of the Be cell is adjusted so that the concentration of an impurity element of Be in the p-GaSb layer 130 is 5.0×10⁻¹⁸ cm⁻³. The growth rate of the p-GaSb layer 130 under the above conditions is 0.30 μm/h, and the film formation is performed for about 100 minutes until the film thickness of the p-GaSb layer 130 comes to be 500 μm; thereafter, the radiation of the Be beam and Ga beam is stopped.

Next, as illustrated in FIG. 14A, the superlattice structure layer 140 having a superlattice structure of InAs/GaSb is formed on the p-GaSb layer 130 to serve as a p-type contact layer. For example, the substrate temperature of the GaSb substrate 110 is lowered to 440° C. while the Sb beam being radiated; thereafter, the radiation of the Sb beam is stopped, and then an In beam and an As beam are radiated. In this case, the beam flux of In is 5.0×10⁻⁸ Torr, the beam flux of As is 5.0×10⁻⁷ Torr, and V/III ratio is 5. The growth rate of InAs under the above conditions is 0.20 μm/h, and the film formation is performed for about 54 seconds until the film thickness of InAs comes to be 2 μm; thereafter, the radiation of the In beam and As beam is stopped. Thereafter, the beams of Ga and Sb are radiated. In this case, the beam flux of Ga is 5.0×10⁻⁸ Torr, the beam flux of Sb is 5.0×10⁻⁷ Torr, and V/III ratio is 10. The growth rate of GaSb under the above conditions is 0.30 μm/h, and the film formation is performed for about 36 seconds until the film thickness of GaSb comes to be 2 μm; thereafter, the radiation of the beams of Ga and Sb is stopped. After that, the above-described film formation of InAs and film formation of GaSb are taken as one cycle, and this cycle is repeated 200 times to form the superlattice structure layer 140 having a total thickness of about 800 nm.

Next, as illustrated in FIG. 14B, the n-InAs layer 150 is formed on the superlattice structure layer 140. For example, after the formation of the superlattice structure layer 140, the n-InAs layer 150 is formed by radiating beams of In, As, and Si. At this time, the temperature of the Si cell is adjusted, so that the concentration of Si as an impurity element with which the n-InAs layer 150 is doped comes to be 5.0×10¹⁸ cm⁻³. In this case, the beam flux of In is 5.0×10⁻⁸ Torr, the beam flux of As is 5.0×10⁻⁷ Torr, and V/III ratio is 5. The growth rate of InAs under the above conditions is 0.20 μm/h, and the film formation is performed for about nine minutes until the film thickness of InAs comes to be 30 μm; thereafter, the radiation of the beams of In and Si is stopped.

After the temperature of the substrate is lowered to 400° C. while the As beam being radiated, the radiation of the As beam is stopped, and then a resultant product where an epitaxial film is formed on the GaSb substrate 110 is taken out from the vacuum chamber of the MBE apparatus.

As described above, the semiconductor crystal substrate according to the present embodiment is manufactured. Although the case in which the GaSb substrate 110 uses an n-GaSb substrate is described in the present embodiment, an InAs substrate or the like may be used in place of the GaSb substrate 110.

### Second Embodiment

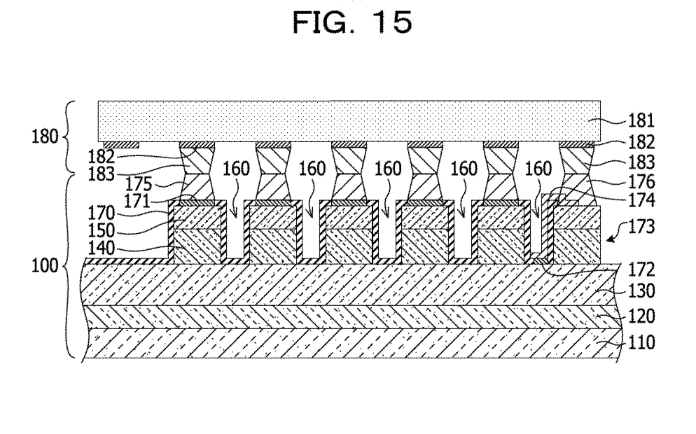

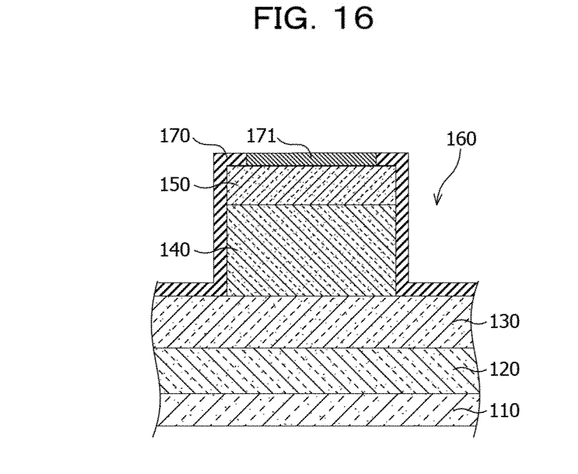

Next, a second embodiment will be described. The present embodiment relates to an infrared detection device manufactured by using the semiconductor crystal substrate according to the first embodiment. FIG. 15 illustrates an overall structure of the infrared detection device according to the present embodiment, and FIG. 16 is a diagram in which a structure of one pixel in the infrared detection device is enlarged and illustrated. In FIGS. 15 and 16, the detail of a multilayer structure of a superlattice structure layer 140 is omitted.

As illustrated in FIGS. 15 and 16, in the infrared detection device according to the present embodiment, a GaSb buffer layer 120, a p-GaSb layer 130, the superlattice structure layer 140, and an n-InAs layer 150 are laminated on a GaSb substrate 110. The GaSb substrate 110 is an n-GaSb (001) substrate, and the GaSb buffer layer 120 has a film thickness of about 100 nm. The p-GaSb layer 130 is formed of p-GaSb having a film thickness of 500 nm and doped with Be as an impurity element. In the present embodiment, the superlattice structure layer 140 is a layer to serve as an infrared absorbing layer, and is formed by an InAs/GaSb superlattice (T2SL) structure. In the present embodiment, the superlattice structure layer 140 may be referred to as an infrared absorbing layer.

For example, the superlattice structure layer 140 is formed by alternately laminating an InAs layer with a film thickness of about 2 nm and a GaSb layer with a film thickness of about 2 nm by 200 cycles, and a film thickness of the formed superlattice structure layer 140 is about 800 nm. The n-InAs layer 150 is formed of n-InAs having a film thickness of about 30 nm and doped with Si as an impurity element. In this embodiment, the p-GaSb layer 130 may be referred to as a first contact layer, and the n-InAs layer 150 may be referred to as a second contact layer.

Further, a pixel separation groove 160 for separating pixels is formed in the n-InAs layer 150 and superlattice structure layer 140, and a passivation film 170 is formed with SiN on a side surface and a bottom surface of the pixel separation groove 160. In the infrared detection device according to the present embodiment, a plurality of pixels separated by the pixel separation grooves 160 is arranged two-dimensionally. An electrode 171 is formed on the n-InAs layer 150 of each pixel separated by the pixel separation grooves 160, and an electrode 172 is formed on the p-GaSb layer 130. In the vicinity of the electrode 172, a wiring support portion 173 is formed by the superlattice structure layer 140 and the n-InAs layer 150, and there is formed a wiring layer 174 extending from the electrode 172 through a side surface of the wiring support portion 173 to an upper surface of the wiring support portion 173. As such, the superlattice structure layer 140 and the n-InAs layer 150 in the wiring support portion 173 do not have a function for infrared detection. The electrodes 171 and 172 are formed of a metal laminated film of Ti/Pt/Au. In the present embodiment, a product formed in the above-discussed manner may be referred to as an infrared detection device or an infrared detection element 100. In the infrared detection device according to the present embodiment, infrared rays entering from a rear surface of the GaSb substrate 110 may be detected.

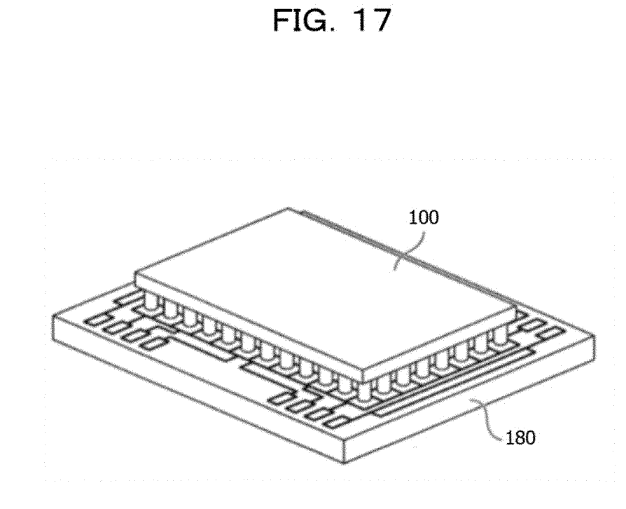

As illustrated in FIG. 15, in the infrared detection device according to the present embodiment, a signal read-out circuit element 180 is connected to the infrared detection element 100. For this connection, in the infrared detection element 100, a bump 175 is formed on the electrode 171, and a bump 176 is formed on the wiring layer 174. The signal read-out circuit element 180 includes a circuit substrate 181, on a surface of which a signal read-out circuit is formed; further, an electrode 182 is formed on the circuit substrate 181, and a bump 183 is formed on the electrode 182. The bumps 175 and 176 and the bump 183 are formed corresponding to each other, and by connecting the corresponding bumps 175 and 176 and the bump 183, the infrared detection element 100 and the signal read-out circuit element 180 are connected to each other. FIG. 17 is a perspective view of the infrared detection device according to the present embodiment.

(Method for Manufacturing Infrared Detection Device)

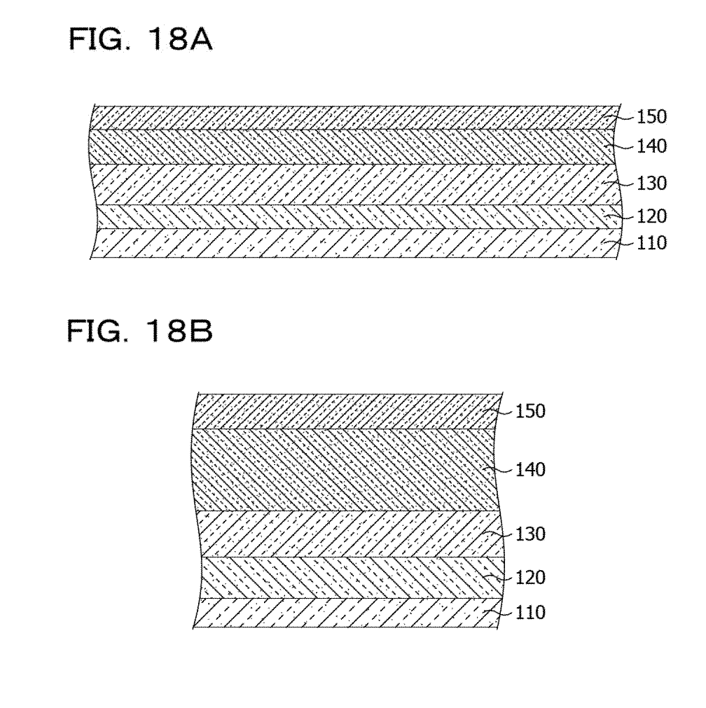

Next, a method for manufacturing the infrared detection device according to the present embodiment will be described with reference to FIGS. 18A to 21B. The infrared detection device according to the present embodiment may be manufactured by using the semiconductor crystal substrate according to the first embodiment. FIGS. 18A, 19A, 20A, and 21A illustrate overall appearances in each manufacturing process, and FIGS. 18B, 19B, 20B, and 21B are diagrams in which a section corresponding to one pixel in each manufacturing process is enlarged and illustrated. In FIGS. 18A to 21B, the detail of the multilayer structure of the superlattice structure layer 140 is omitted.

First, as illustrated in FIGS. 18A and 18B, a semiconductor crystal substrate is prepared in which the GaSb buffer layer 120, the p-GaSb layer 130, the superlattice structure layer 140, and the n-InAs layer 150 are laminated and formed in sequence on the GaSb substrate 110. The above-mentioned semiconductor crystal substrate corresponds to the semiconductor crystal substrate according to the first embodiment. Therefore, details of the GaSb buffer layer 120, p-GaSb layer 130, superlattice structure layer 140, and n-InAs layer 150 will not be described.

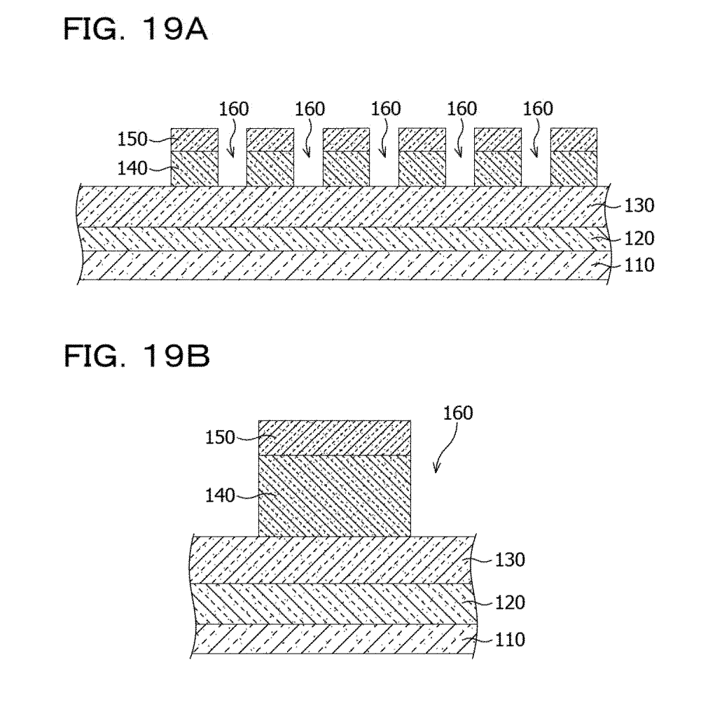

Next, as illustrated in FIGS. 19A and 19B, part of the n-InAs layer 150 and part of the superlattice structure layer 140 are removed to form the pixel separation groove 160. For example, a photoresist is applied on the n-InAs layer 150 to perform exposure and development by an exposure apparatus, thereby forming a resist pattern (not illustrated) having an opening in a region where the pixel separation groove 160 is formed. Thereafter, by dry etching using a CF₄-based gas, the n-InAs layer 150 and the superlattice structure layer 140 in a region where the resist pattern is not formed are removed to form the pixel separation groove 160. By forming the pixel separation grooves 160 as described above, pixels of a mesa structure separated by the pixel separation grooves 160 are formed. In the present embodiment, the size of a pixel formed is 50 μm×50 μm, and 256×256 pixels are formed in the infrared detection device.

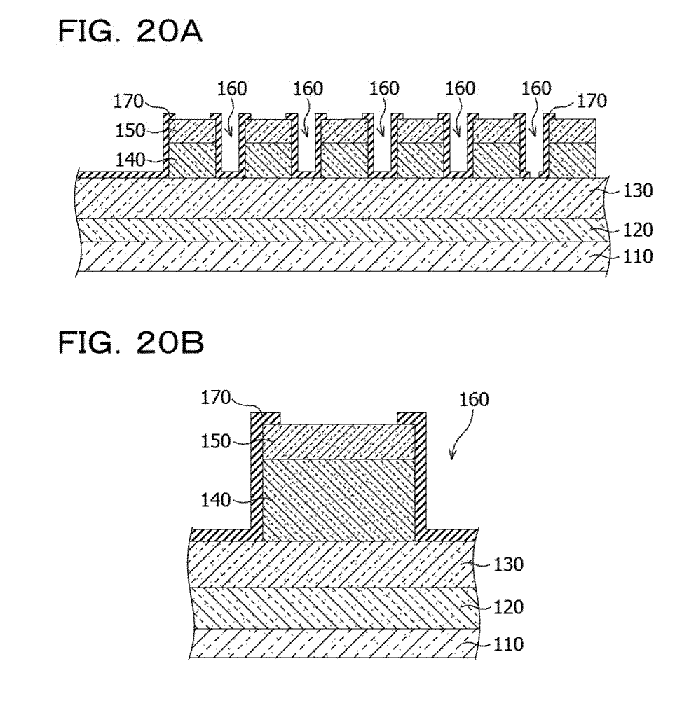

Next, as illustrated in FIGS. 20A and 20B, the passivation film 170 is formed on the n-InAs layer 150 of each pixel, the side surfaces of the n-InAs layer 150 and the superlattice structure layer 140, and the p-GaSb layer 130 between the pixels. The passivation film 170 is formed by depositing an SiN film having a film thickness of 100 nm by plasma chemical vapor deposition (CVD) using SiH₄- and NH₃-based gases.

Thereafter, a photoresist is applied, and the exposure apparatus performs the exposure and development to form a resist pattern (not illustrated) having an opening in a region where the electrodes 171 and 172 are to be formed. After that, the passivation film 170 in a region where the resist pattern is not formed is removed by dry etching using a CF₄-based etching gas to expose the n-InAs layer 150 and the p-GaSb layer 130 in this region.

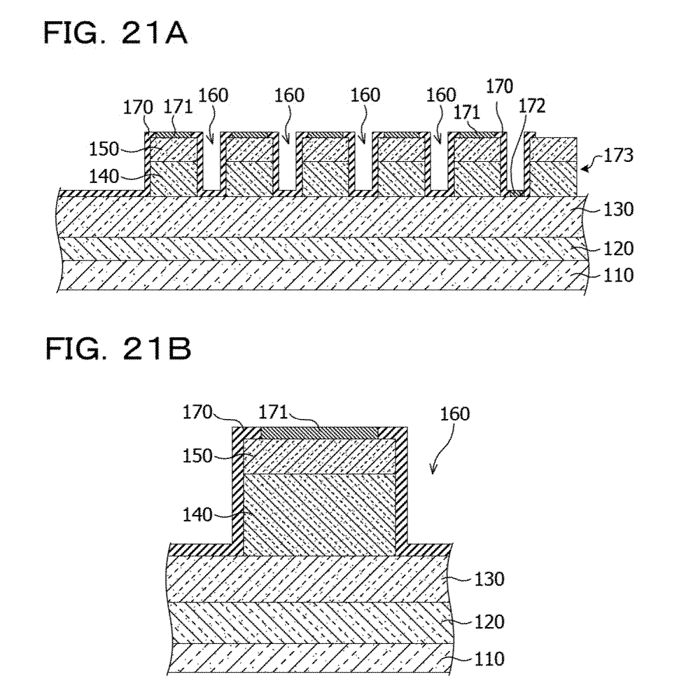

Subsequently, as illustrated in FIGS. 21A and 21B, the electrode 171 is formed on the exposed n-InAs layer 150, and the electrode 172 is formed on the p-GaSb layer 130. For example, after the formation of a resist pattern (not illustrated) having an opening in the region where the electrode 171 and the electrode 172 are to be formed, a metal laminated film made of Ti/Pt/Au is formed by vacuum deposition, sputtering, or the like. Thereafter, through the immersion in an organic solvent or the like, the metal laminated film formed on the resist pattern is removed by lift-off along with the resist pattern. As a result, with the remaining metal laminated film, the electrode 171 is formed on the n-InAs layer 150 and the electrode 172 is formed on the p-GaSb layer 130.

Thereafter, as illustrated in FIG. 15, the wiring layer 174 is formed on the electrode 172 and the side surface and upper surface of the wiring support portion 173, and the bump 175 is formed on the electrode 171; in addition, the bump 176 is formed on the wiring layer 174 on the wiring support portion 173. The bumps 175 and 176 formed in this manner and the bump 183 formed in the signal read-out circuit element 180 are bonded to each other by flip-chip bonding, thereby connecting the infrared detection element 100 and the signal read-out circuit element 180. As a result, the infrared detection device according to the present embodiment is manufactured.

The contents other than those described above are the same as those in the first embodiment.

### Third Embodiment

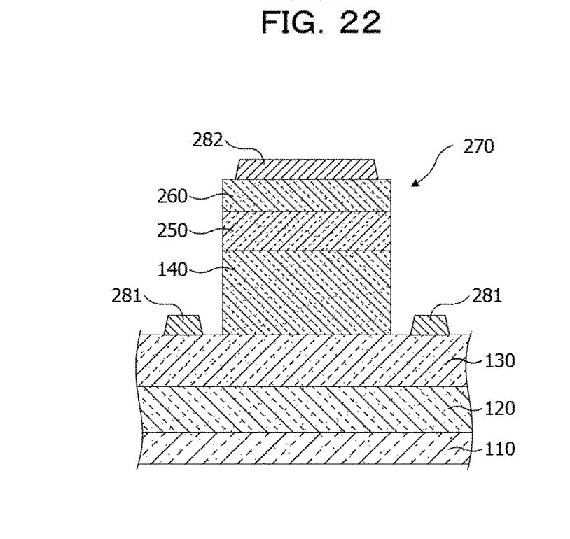

Next, a third embodiment will be described. The present embodiment is a GaSb-based semiconductor laser, which is an optical semiconductor device manufactured by using the semiconductor crystal substrate according to the first embodiment. FIG. 22 illustrates a structure of a semiconductor laser according to the present embodiment. Note that in FIG. 22, the detail of a multilayer structure of a superlattice structure layer 140 is omitted.

In the semiconductor laser of the present embodiment, a GaSb buffer layer 120, a p-GaSb layer 130, the superlattice structure layer 140, an n-GaSb layer 250, and an n-InAs layer 260 are laminated on a GaSb substrate 110. Accordingly, in the semiconductor laser according to the present embodiment, a semiconductor crystal substrate is used in which the GaSb buffer layer 120, the p-GaSb layer 130, and the superlattice structure layer 140 are laminated in sequence on the GaSb substrate 110. In the present embodiment, the p-GaSb layer 130 may be referred to as a first cladding layer, the n-GaSb layer 250 may be referred to as a second cladding layer, and the superlattice structure layer 140 may be referred to as a multi-quantum well (MQW) layer.

In this embodiment, the n-GaSb layer 250 and the n-InAs layer 260 are sequentially formed by MBE on the superlattice structure layer 140 of the semiconductor crystal substrate according to the first embodiment. The n-GaSb layer 250 formed has a film thickness of about 100 nm and is doped with Si as an impurity element, and the n-InAs layer 260 has a film thickness of about 30 nm and is doped with Si as an impurity element.

Next, the n-InAs layer 260, n-GaSb layer 250, and superlattice structure layer 140 are partially removed to form a mesa structure 270. For example, the n-InAs layer 260, n-GaSb layer 250, and superlattice structure layer 140 are partially removed by dry etching using a CF₄-based gas as an etching gas to expose the p-GaSb layer 130, thereby forming the mesa structure 270.

Next, a lower electrode 281 is formed on the p-GaSb layer 130 that is exposed by forming the mesa structure 270, and an upper electrode 282 is formed on the n-InAs layer 260. The lower electrode 281 and the upper electrode 282 are each formed of, for example, a metal laminated film of Ti/Pt/Au or the like.

Thereafter, the GaSb substrate 110 is cleaved in a stripe shape having a width of 20 μm and a length of 50 μm, whereby the semiconductor laser according to the present embodiment is manufactured. This semiconductor laser is an end-surface emission laser with a wavelength of 3.0 μm.

### Fourth Embodiment

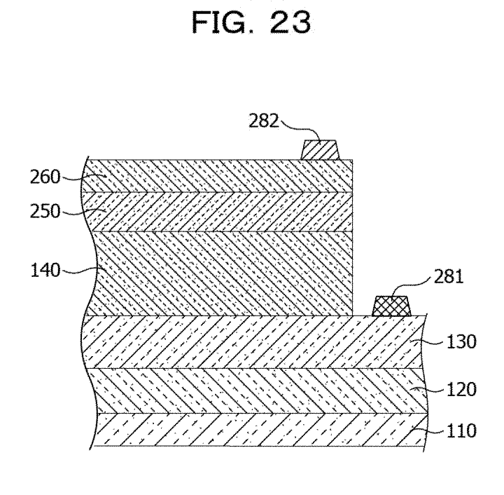

Next, a fourth embodiment will be described. The present embodiment is a GaSb-based light emitting diode (LED), which is an optical semiconductor device manufactured by using the semiconductor crystal substrate according to the first embodiment. FIG. 23 illustrates a structure of the light emitting diode according to the present embodiment. In FIG. 23, the detail of a multilayer structure of a superlattice structure layer 140 is omitted.

The light emitting diode according to the present embodiment uses the semiconductor crystal substrate according to the first embodiment, and a film similar to that in the third embodiment is epitaxially grown by MBE; thereafter, a lower electrode 281 and an upper electrode 282 are formed.

Then, by being cleaved in a chip shape of 50 μm×50 μm, the light emitting diode according to the present embodiment is manufactured. In this light emitting diode, since the light is emitted from the side where the n-InAs layer 260 is formed, it is preferable that a region on the n-InAs layer 260 where the upper electrode 282 is not formed be wide.

### Fifth Embodiment

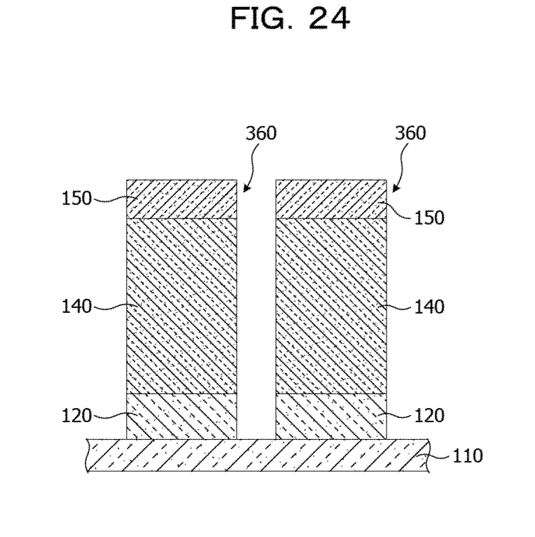

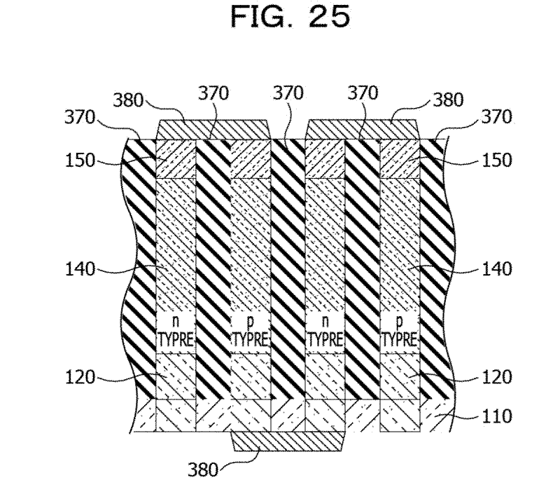

Next, a fifth embodiment will be described. The present embodiment is a thermoelectric conversion element manufactured by using the semiconductor crystal substrate according to the first embodiment. The thermoelectric conversion element according to the present embodiment will be described with reference to FIGS. 24 and 25. In FIGS. 24 and 25, the detail of a multilayer structure of a superlattice structure layer 140 is omitted.

The thermoelectric conversion element of the present embodiment uses a semiconductor crystal substrate in which a GaSb buffer layer 120, the superlattice structure layer 140, and an n-InAs layer 150 are laminated in sequence on a GaSb substrate 110. For example, in the thermoelectric conversion element of the present embodiment, the GaSb buffer layer 120, the superlattice structure layer 140, and the n-InAs layer 150 are formed on the GaSb substrate 110. In the present embodiment, in the superlattice structure layer 140, a GaSb layer having a film thickness of about 5 nm and an InAs layer having a film thickness of about 5 nm are alternately formed, where 500 pairs of these GaSb and InAs are formed. The n-InAs layer 150 is formed of an n-InAs film with a thickness of 30 nm.

Next, the n-InAs layer 150, the superlattice structure layer 140, and the GaSb buffer layer 120 are removed to form a mesa structure 360. For example, the n-InAs layer 150, superlattice structure layer 140, and GaSb buffer layer 120 are removed by dry etching using a CF₄-based gas as an etching gas, thereby forming the mesa structure 360. This state is illustrated in FIG. 24.

Next, an SiO₂ film 370 is formed by CVD, and a gap in the mesa structure 360 is filled with the SiO₂ film 370. Thereafter, the rear surface of the GaSb substrate 110 is polished by chemical mechanical polishing (CMP), so that the thickness of the GaSb substrate 110 is reduced to be approximately 3 μm. After that, impurity ions to be n-type and p-type dopants are implanted by an ion implantation method, and activation annealing is performed to form n-type and p-type regions. Then, electrodes 380 are formed on one side and the other side in such a manner that the respective constituent elements are connected in series. The electrode 380 is made of, for example, a metal laminated film of Ti/Pt/Au.

Thus far, the embodiments have been described in detail; however, the embodiments are not limited to any specific embodiments, and various modifications and changes may be made within the scope of the appended claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor crystal substrate comprising:
a crystal substrate whose principal surface is inclined relative to a (001) plane; and
a superlattice structure layer formed by alternately laminating a first superlattice formation layer and a second superlattice formation layer over the principal surface of the crystal substrate,
wherein the first superlattice formation layer is formed of a layer of Ga₁₋ₓ₁Inₓ₁As_{y1}Sb_{1-y1} (0≤x1≤0.1, 0≤y1≤0.1), and a value of a standard deviation with respect to a mean value of atomic step widths in an inclination direction of a surface of the first superlattice formation layer (a value of the standard deviation/the mean value) is equal to or greater than 0 and equal to or smaller than 0.20, and
the second superlattice formation layer is formed of a layer of Ga₁₋ₓ₂Inₓ₂AS_{y2}Sb_{1-y2} (0.9≤x2≤1, 0.9≤y2≤1), and a value of a standard deviation with respect to a mean value of atomic step widths in an inclination direction of a surface of the second superlattice formation layer (a value of the standard deviation/the mean value) is equal to or greater than 0 and equal to or smaller than 0.40.

2. The semiconductor crystal substrate according to claim 1,
wherein an angle at which the principal surface is inclined relative to the (001) plane in the crystal substrate is equal to or greater than 0.1° and equal to or smaller than 10°.

3. The semiconductor crystal substrate according to claim 1,
wherein the crystal substrate is formed of a material containing any of GaAs, InP, InAs, Si, and GaSb.

4. The semiconductor crystal substrate according to claim 1,
wherein the first superlattice formation layer is formed of a GaSb layer, and
the second superlattice formation layer is formed of an InAs layer.

5. The semiconductor crystal substrate according to claim 1,
wherein a buffer layer is formed between the crystal substrate and the superlattice structure layer, and
the buffer layer is formed of a material containing GaSb.

6. A device comprising:
a crystal substrate whose principal surface is inclined relative to a (001) plane; and
a superlattice structure layer formed by alternately laminating a first superlattice formation layer and a second superlattice formation layer over the principal surface of the crystal substrate,
wherein the first superlattice formation layer is formed of a layer of Ga₁₋ₓ₁Inₓ₁As_{y1}Sb_{1-y1} (0≤x1≤0.1, 0≤y1≤0.1), and a value of a standard deviation with respect to a mean value of atomic step widths in an inclination direction of a surface of the first superlattice formation layer (a value of the standard deviation/the mean value) is equal to or greater than 0 and equal to or smaller than 0.20, and
the second superlattice formation layer is formed of a layer of Ga₁₋ₓ₂Inₓ₂AS_{y2}Sb_{1-y2} (0.9≤x2≤1, 0.9≤y2≤1), and a value of a standard deviation with respect to a mean value of atomic step widths in an inclination direction of a surface of the second superlattice formation layer (a value of the standard deviation/the mean value) is equal to or greater than 0 and equal to or smaller than 0.40.

7. The device according to claim 6,
wherein the device is an infrared detection device,
the device further includes:
a first contact layer formed of a compound semiconductor over the principal surface of the crystal substrate; and
a second contact layer formed of a compound semiconductor over the superlattice structure layer.

8. The device according to claim 7,
wherein an angle at which the principal surface is inclined relative to the (001) plane in the crystal substrate is equal to or greater than 0.1° and equal or smaller than 10°.

9. The device according to claim 7,
wherein the crystal substrate is formed of a material containing any of GaAs, InP, InAs, Si, and GaSb.

10. The device according to claim 7,
wherein the first superlattice formation layer is formed of a GaSb layer, and
the second superlattice formation layer is formed of an InAs layer.

11. The device according to claim 7,
wherein a conductive type of the first contact layer is a first conductivity type, and the first contact layer of the first conductive type is formed of a material containing GaSb, and
a conductive type of the second contact layer is a second conductive type, and the second contact layer of the second conductive type is formed of a material containing InAs.

12. The device according to claim 7,
wherein a buffer layer is formed between the crystal substrate and the superlattice structure layer, and
the buffer layer is formed of a material containing GaSb.

13. The device according to claim 7,
wherein pixel separation grooves for separating each individual pixel are formed in the second contact layer and the superlattice structure layer.

14. The device according to claim 6,
wherein the device is an optical semiconductor device,
the device further includes:
a first cladding layer formed of a compound semiconductor over the principal surface of the crystal substrate; and
a second cladding layer formed of a compound semiconductor over the superlattice structure layer.

15. The device according to claim 14,
wherein a conductive type of the first cladding layer is a first conductive type, and the first cladding layer of the first conductive type is formed of a material containing GaSb, and
a conductive type of the second cladding layer is a second conductive type, and the second cladding layer of the second conductive type is formed of a material containing GaSb.

16. The device according to claim 6,
wherein the device is a thermoelectric conversion element,
the thermoelectric conversion element further includes an n-type region of a mesa structure and a p-type region of the mesa structure formed by implanting impurity ions in the superlattice structure layer, and electrodes for coupling the n-type region of the mesa structure and the p-type region of the mesa structure to each other.

17. A method for manufacturing a semiconductor crystal substrate, the method comprising:
forming a superlattice structure layer by alternately laminating a first superlattice formation layer and a second superlattice formation layer by epitaxial growth over a crystal substrate whose principal surface is inclined relative to a (001) plane,
wherein the first superlattice formation layer is formed of a layer of Ga₁₋ₓ₁Inₓ₁As_{y1}Sb_{1-y1} (0≤x1≤0.1, 0≤y1≤0.1), and a value of a standard deviation with respect to a mean value of atomic step widths in an inclination direction of a surface of the first superlattice formation layer (a value of the standard deviation/the mean value) is equal to or greater than 0 and equal to or smaller than 0.20, and
the second superlattice formation layer is formed of a layer of Ga₁₋ₓ₂Inₓ₂ASy₂Sb_{1-y2} (0.9≤x2≤1, 0.9≤y2≤1), and a value of a standard deviation with respect to a mean value of atomic step widths in an inclination direction of a surface of the second superlattice formation layer (a value of the standard deviation/the mean value) is equal to or greater than 0 and equal to or smaller than 0.40.

18. The method according to claim 16,
wherein the superlattice structure layer is formed by molecular beam epitaxy.
